(19) United States
(12) Patent Application Publication
(10) Pub. No.: US 2025/0023548 A1
(43) Pub. Date: Jan. 16, 2025

(54) ACOUSTIC WAVE DEVICE

(71) Applicant: Murata Manufacturing Co., Ltd., Nagaokakyo-shi (JP)

(72) Inventors: Kazunori INOUE, Nagaokakyo-shi (JP); Masakazu MIMURA, Nagaokakyo-shi (JP)

(21) Appl. No.: 18/900,426

(22) Filed: Sep. 27, 2024

Related U.S. Application Data
(63) Continuation of application No. PCT/JP2023/012885, filed on Mar. 29, 2023.
(60) Provisional application No. 63/325,825, filed on Mar. 31, 2022.

(51) Int. Cl. H03H 9/17; H03H 9/02; H03H 9/13

(52) U.S. Cl. CPC H03H 9/174; H03H 9/02031; H03H 9/02157; H03H 9/02228; H03H 9/13; H03H 9/176

(57) ABSTRACT

An acoustic wave device includes a support substrate including a space portion, a piezoelectric body layer on the support substrate, a functional electrode on the piezoelectric body layer and at least partially overlapping with the space portion in plan view along a lamination direction of the support substrate and the piezoelectric body layer, and a structure on the piezoelectric body layer and having a smaller coefficient of thermal linear expansion than the piezoelectric body layer. The structure includes a region located in a region of the piezoelectric body layer other than a region where the functional electrode is provided and that does not overlap with the space portion in the plan view.

### CROSS REFERENCE TO RELATED APPLICATIONS

This application claims the benefit of priority to Provisional Application No. 63/325,825 filed on Mar. 31, 2022 and is a Continuation Application of PCT Application No. PCT/JP2023/012885 filed on Mar. 29, 2023. The entire contents of each application are hereby incorporated herein by reference.

### BACKGROUND OF THE INVENTION

### 1. Field of the Invention

The present disclosure relates to acoustic wave devices each including a piezoelectric layer (piezoelectric body layer).

### 2. Description of the Related Art

For example, Japanese Unexamined Patent Application Publication No. 2012-257019 discloses an acoustic wave device that uses plate waves. The acoustic wave device described in Japanese Unexamined Patent Application Publication No. 2012-257019 includes a support, a piezoelectric substrate, and an IDT electrode. The support has a space portion. The piezoelectric substrate is provided on the support so as to overlap with the space portion. The IDT electrode is provided on the piezoelectric substrate so as to overlap with the space portion. In the acoustic wave device, a plate wave is excited by the IDT electrode. An end edge portion of the space portion does not include a linear portion extending parallel to the propagation direction of the plate wave excited by the IDT electrode.

There has recently been a demand for an acoustic wave device having a membrane portion that can easily detect cracks occurring in the membrane portion.

### SUMMARY OF THE INVENTION

Example embodiments of the present invention provide acoustic wave devices that are each able to easily detect cracks occurring in a membrane portion.

An acoustic wave device according to an example embodiment of the present invention includes a support substrate including a space portion on one main surface thereof, a piezoelectric body layer on the one main surface of the support substrate, a functional electrode on the piezoelectric body layer and at least partially overlapping with the space portion in plan view along a lamination direction of the support substrate and the piezoelectric body layer, and at least one structure on the piezoelectric body layer and having a smaller coefficient of thermal linear expansion than the piezoelectric body layer, and the at least one structure includes a region located in a region of the piezoelectric body layer other than a region where the functional electrode is provided and that does not overlap with the space portion in the plan view.

Example embodiments of the present invention provide acoustic wave devices that are each able to easily detect cracks occurring in a membrane portion.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1A is a schematic perspective view illustrating an appearance of an acoustic wave device according to an example embodiment of the present invention.

FIG. 1B is a plan view illustrating an electrode structure on a piezoelectric layer.

FIG. 2 is a cross-sectional view of a portion taken along line A-A in FIG. 1A.

FIG. 3A is a schematic elevational cross-sectional view for explaining a Lamb wave propagating through a piezoelectric film of an acoustic wave device of the related art.

FIG. 3B is a schematic elevational cross-sectional view for explaining a wave in an acoustic wave device according to an example embodiment of the present invention.

FIG. 4 is a schematic view illustrating a bulk wave when a voltage is applied between a first electrode and a second electrode such that the second electrode has a higher potential than the first electrode.

FIG. 5 is a graph illustrating resonance characteristics of an acoustic wave device according to an example embodiment of the present invention.

FIG. 6 is a graph illustrating a relationship between d/2p and a fractional band width of a resonator in an acoustic wave device according to an example embodiment of the present invention.

FIG. 7 is a plan view of another acoustic wave device according to an example embodiment of the present invention.

FIG. 8 is a reference diagram illustrating an example of resonance characteristics of an acoustic wave device according to an example embodiment of the present invention.

FIG. 9 is a diagram illustrating a relationship between a fractional band width and a phase rotation amount of a spurious impedance normalized by about 180 degrees as a magnitude of spurious when a large number of acoustic wave resonators are configured.

FIG. 10 is a diagram illustrating a relationship among d/2p, a metallization ratio MR, and a fractional band width.

FIG. 11 is a diagram illustrating a map of the fractional band width with respect to Euler angles (0°, θ, ψ) of LiNbO₃ when d/p is infinitely close to 0.

FIG. 12 is a partially cutaway perspective view for explaining an acoustic wave device according to an example embodiment of the present invention.

FIG. 13 is a plan view illustrating an acoustic wave device according to an example embodiment of the present invention.

FIG. 14 is a cross-sectional view taken along line XIV-XIV in FIG. 13.

FIG. 15 is a plan view of an acoustic wave device without a structure.

FIG. 16 is a plan view illustrating a first modification of the acoustic wave device in FIG. 13.

FIG. 17 is a plan view illustrating a second modification of the acoustic wave device in FIG. 13.

FIG. 18 is a cross-sectional view taken along line XVIII-XVIII in FIG. 17.

### DETAILED DESCRIPTION OF THE EXAMPLE EMBODIMENTS

Hereinafter, example embodiments of the present invention will be described with reference to the accompanying drawings. The following description is merely exemplary in nature and is not intended to limit the present invention, the application of the present invention, or the use of the present invention. The drawings are schematic, and the ratio of dimensions and the like do not necessarily correspond to the real ones.

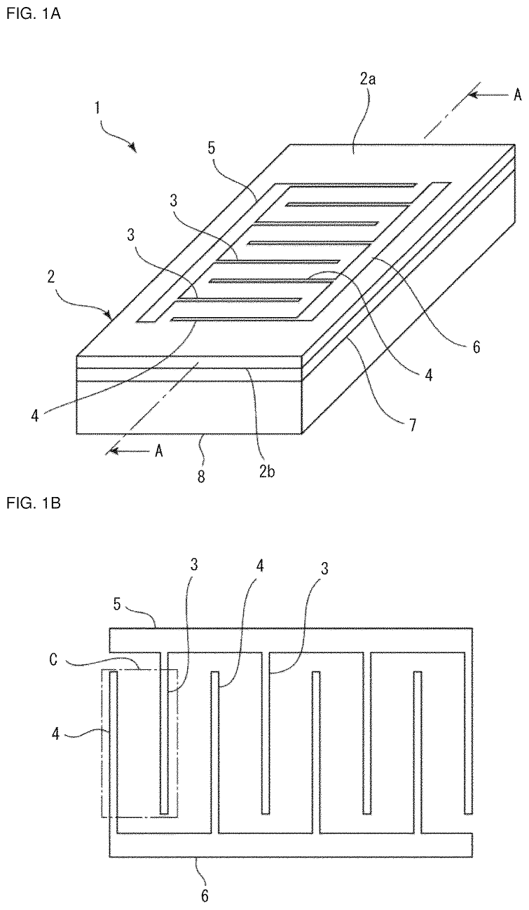

With reference to FIGS. 1A to 12, acoustic wave devices according to example embodiments of the present invention will be described.

An acoustic wave device according to an example embodiment of the present invention includes a piezoelectric layer made of lithium niobate or lithium tantalate, for example, and a first electrode and a second electrode facing each other in a direction intersecting a thickness direction of the piezoelectric layer.

In the acoustic wave device according to the present example embodiment, a first-order thickness-shear mode bulk wave is used.

In an acoustic wave device according to an example embodiment, the first electrode and the second electrode are adjacent electrodes, and d/p is, for example, less than or equal to about 0.5, where d is the thickness of the piezoelectric layer and p is the center-to-center distance between the first electrode and the second electrode. This can increase a Q value even when downsizing is promoted.

In an acoustic wave device according to an example embodiment, a Lamb wave is used as a plate wave, and resonance characteristics due to the Lamb wave can be obtained.

An acoustic wave device according to an example embodiment of the present invention includes a piezoelectric layer made of lithium niobate or lithium tantalate, for example, and an upper electrode and a lower electrode facing each other in the thickness direction of the piezoelectric layer with the piezoelectric layer interposed therebetween, and uses a bulk wave.

Hereinafter, the present invention will become apparent from the description of example embodiments of acoustic wave devices according to the present invention.

It should be noted that each example embodiment described in the present disclosure is an example, and partial replacement or combination of configurations is possible between different example embodiments.

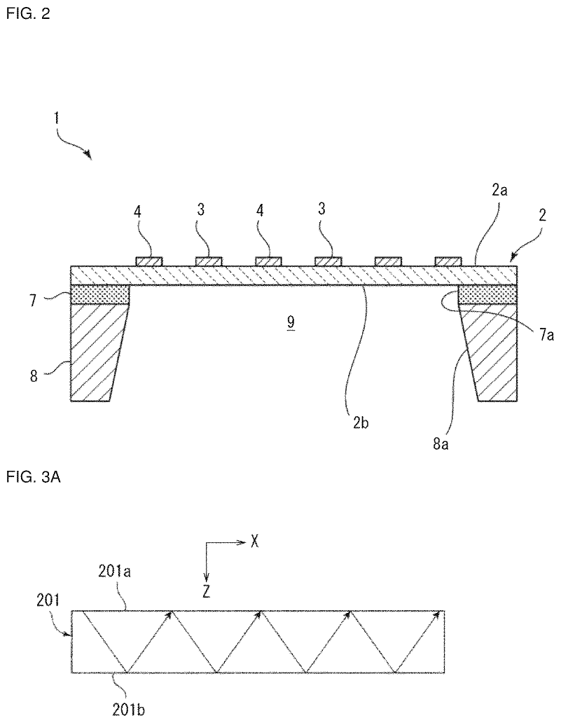

FIG. 1A is a schematic perspective view illustrating an appearance of an acoustic wave device according to an example embodiment. FIG. 1B is a plan view illustrating an electrode structure on a piezoelectric layer. FIG. 2 is a cross-sectional view of a portion taken along line A-A in FIG. 1A.

An acoustic wave device 1 includes a piezoelectric layer 2 made of LiNbO₃, for example. The piezoelectric layer 2 may be made of LiTaO₃, for example. The cut-angle of LiNbO₃ or LiTaO₃ is a Z-cut in this example embodiment, but may be a rotated Y-cut or X-cut. The propagation directions of, for example, Y propagation and X propagation about ±30° are preferable. The thickness of the piezoelectric layer 2 is not particularly limited, but is, for example, preferably more than or equal to about 50 nm and less than or equal to about 1000 nm in order to effectively excite a first-order thickness-shear mode.

The piezoelectric layer 2 includes a first main surface 2a and a second main surface 2b facing each other. An electrode 3 and an electrode 4 are provided on the first main surface 2a. Here, the electrode 3 is an example of a “first electrode” and the electrode 4 is an example of a “second electrode”. In FIGS. 1A and 1B, a plurality of the electrodes 3 include a plurality of first electrode fingers connected to a first busbar 5. A plurality of the electrodes 4 include a plurality of second electrode fingers connected to a second busbar 6. The plurality of electrodes 3 and the plurality of electrodes 4 are interdigitated with each other.

The electrode 3 and the electrode 4 have a rectangular or substantially rectangular shape and have a length direction. In a direction orthogonal or substantially orthogonal to the length direction, the electrode 3 and the electrode 4 adjacent thereto face each other. The plurality of electrodes 3 and 4, the first busbar 5, and the second busbar 6 define an interdigital transducer (IDT) electrode. The length direction of the electrodes 3 and 4 and the direction orthogonal or substantially orthogonal to the length direction of the electrodes 3 and 4 each are a direction intersecting a thickness direction of the piezoelectric layer 2. Therefore, it can also be said that the electrode 3 and the electrode 4 adjacent thereto face each other in the direction intersecting the thickness direction of the piezoelectric layer 2.

The length direction of the electrodes 3 and 4 may be replaced with the direction orthogonal or substantially orthogonal to the length direction of the electrodes 3 and 4 illustrated in FIGS. 1A and 1B. That is, the electrodes 3 and 4 may extend in the direction in which the first busbar 5 and the second busbar 6 extend in FIGS. 1A and 1B. In this case, the first busbar 5 and the second busbar 6 extend in the direction in which the electrodes 3 and 4 extend in FIGS. 1A and 1B.

A plurality of pairs of structures in which the electrode 3 connected to one potential and the electrode 4 connected to the other potential are adjacent to each other are provided in the direction orthogonal or substantially orthogonal to the length direction of the electrodes 3 and 4 described above. Here, the electrode 3 and the electrode 4 being adjacent to each other refers not to a case where the electrode 3 and the electrode 4 are arranged so as to be in direct contact with each other but to a case where the electrode 3 and the electrode 4 are arranged with an interval therebetween.

When the electrode 3 and the electrode 4 are adjacent to each other, an electrode connected to a hot electrode or a ground electrode, including the other electrodes 3 and 4, is not arranged between the electrode 3 and the electrode 4. The number of pairs need not be integer pairs, but may be 1.5 pairs, 2.5 pairs, or the like. The center-to-center distance between the electrodes 3 and 4, that is, the pitch is, for example, preferably in the range of more than or equal to about 1 μm and less than or equal to about 10 μm. In addition, the center-to-center distance between the electrodes 3 and 4 is a distance connecting the center of the width dimension of the electrode 3 in the direction orthogonal or substantially orthogonal to the length direction of the electrode 3 and the center of the width dimension of the electrode 4 in the direction orthogonal or substantially orthogonal to the length direction of the electrode 4. Further, in a case where at least one of the electrodes 3 and 4 defines a plurality of pairs (when the electrodes 3 and 4 define a pair of electrode sets, there are 1.5 or more pairs of electrode sets), the center-to-center distance between the electrodes 3 and 4 refers to the average value of the center-to-center distances between the respective adjacent electrodes 3 and 4 of the 1.5 or more pairs of electrodes 3 and 4. In addition, the width of the electrodes 3 and 4, that is, the dimension of the electrodes 3 and 4 in their facing direction, is, for example, preferably in the range of more than or equal to about 150 nm and less than or equal to about 1000 nm. The center-to-center distance between the electrodes 3 and 4 is a distance connecting the center of the dimension (width dimension) of the electrode 3 in the direction orthogonal or substantially orthogonal to the length direction of the electrode 3 and the center of the dimension (width dimension) of the electrode 4 in the direction orthogonal to the length direction of the electrode 4.

In example since the Z-cut this embodiment, piezoelectric layer is used, the direction orthogonal or substantially orthogonal to the length direction of the electrodes 3 and 4 is a direction orthogonal or substantially orthogonal to the polarization direction of the piezoelectric layer 2. This does not apply when a piezoelectric body of another cut-angle is used as the piezoelectric layer 2. Here, the term “orthogonal” is not limited to strictly orthogonal but may be substantially orthogonal (an angle between the direction orthogonal to the length direction of the electrodes 3 and 4 and the polarization direction is, for example, about 90°+) 10°.

A support 8 is laminated on the second main surface 2b side of the piezoelectric layer 2 with an insulating layer 7 interposed therebetween. The insulating layer 7 and the support 8 have a frame shape and include cavities 7a and 8a as illustrated in FIG. 2. A space portion 9 is thus provided. The space portion 9 is provided so as not to interfere with the vibration of an excitation region C of the piezoelectric layer 2. Therefore, the support 8 is laminated on the second main surface 2b with the insulating layer 7 interposed therebetween at a position not overlapping with a portion where at least a pair of electrodes 3 and 4 are provided. The insulating layer 7 need not be provided. Therefore, the support 8 can be directly or indirectly laminated on the second main surface 2b of the piezoelectric layer 2.

The insulating layer 7 is made of silicon oxide, for example. However, the insulating layer 7 can be made of an appropriate insulating material such as, for example, silicon oxynitride or alumina in addition to silicon oxide. The support 8 is made of Si, for example. The plane orientation of the surface of Si on the piezoelectric layer 2 side may be (100), (110), or (111). Preferably, for example, high-resistance Si having a resistivity of more than or equal to about 4 kQ is preferably used. However, the support 8 can also be made using an appropriate insulating material or semiconductor material. Examples of the material of the support 8 include piezoelectric bodies such as aluminum oxide, lithium tantalate, lithium niobate, and quartz crystal, various ceramics such as alumina, magnesia, sapphire, silicon nitride, aluminum nitride, silicon carbide, zirconia, cordierite, mullite, steatite, and forsterite, dielectrics such as diamond and glass, semiconductors such as gallium nitride, and the like.

The plurality of electrodes 3 and 4, the first busbar 5, and the second busbar 6 are made of an appropriate metal or alloy such as, for example, Al or an AlCu alloy. In this example embodiment, for example, the electrodes 3 and 4, the first busbar 5, and the second busbar 6 have a structure in which an Al film is laminated on a Ti film. A material other than the Ti film may be used for a close contact layer.

At the time of driving, an AC voltage is applied between the plurality of electrodes 3 and the plurality of electrodes 4. More specifically, an AC voltage is applied between the first busbar 5 and the second busbar 6. This makes it possible to obtain resonance characteristics using a bulk wave in the first-order thickness-shear mode excited in the piezoelectric layer 2.

In the acoustic wave device 1, for example, d/p is less than or equal to about 0.5, where d is the thickness of the piezoelectric layer 2, and p is the center-to-center distance between any adjacent electrodes 3 and 4 of the plurality of pairs of electrodes 3 and 4. Therefore, the bulk wave in the first-order thickness-shear mode is effectively excited, and good resonance characteristics can be obtained. More preferably, for example, d/p is less than or equal to about 0.24, in which case even better resonance characteristics can be obtained.

In a case where at least one of the electrodes 3 and 4 defines a plurality of pairs as in this example embodiment, that is, in a case where, when the electrodes 3 and 4 define a pair of electrode sets, the electrodes 3 and 4 provide 1.5 or more pairs, the center-to-center distance p between the adjacent electrodes 3 and 4 is an average distance of the center-to-center distances between the respective adjacent electrodes 3 and 4.

Since the acoustic wave device 1 according to this example embodiment has the configuration described above, even when the number of pairs of the electrodes 3 and 4 is reduced in an attempt to downsize, the Q value is not easily reduced. This is because the resonator does not require reflectors on both sides and has a small propagation loss. In addition, the reason why the above reflector is not required is that the bulk wave in the first-order thickness-shear mode is used.

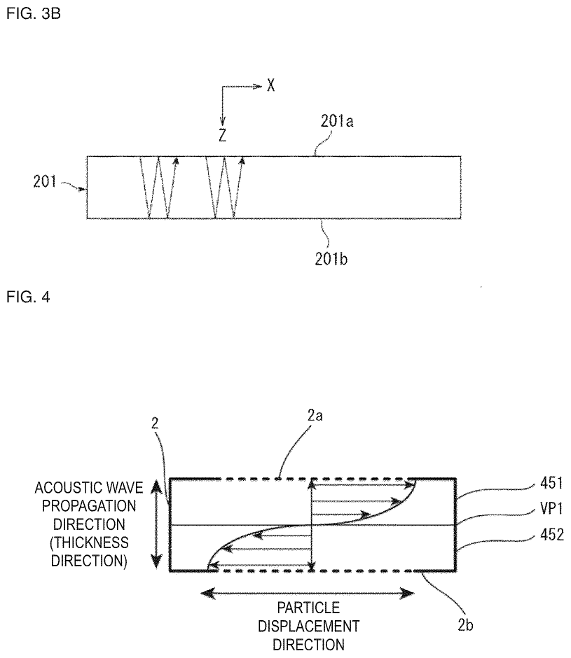

The difference between the Lamb wave used in the acoustic wave device of the related art and the first-order thickness-shear mode bulk wave described above will be described with reference to FIGS. 3A and 3B.

FIG. 3A is a schematic elevational cross-sectional view for explaining a Lamb wave propagating through a piezoelectric film of an acoustic wave device of the related art. The acoustic wave device of the related art is described, for example, in Japanese Unexamined Patent Application Publication No. 2012-257019. As illustrated in FIG. 3A, a wave propagates through a piezoelectric film 201 as indicated by arrows in the acoustic wave device of the related art. Here, the piezoelectric film 201 includes a first main surface 201a and a second main surface 201b, which face each other, and a thickness direction connecting the first main surface 201a and the second main surface 201b is the Z direction. The X direction is a direction in which electrode fingers of an IDT electrode are arranged. As illustrated in FIG. 3A, the Lamb wave propagates in the X direction. Although the piezoelectric film 201 vibrates as a whole because of the plate wave, since the wave propagates in the X direction, reflectors are arranged on both sides to obtain resonance characteristics. Therefore, a propagation loss of waves occurs, and the Q value decreases when the size is reduced, that is, when the number of pairs of electrode fingers is reduced.

On the other hand, as illustrated in FIG. 3B, in the acoustic wave device 1 of this example embodiment, since the vibration displacement is in the thickness-shear direction, the wave substantially propagates in the direction connecting the first main surface 2a and the second main surface 2b of the piezoelectric layer 2, that is, the Z direction, and resonates. Specifically, the X direction component of the wave is significantly smaller than the Z direction component. Since resonance characteristics are obtained by the propagation of the wave in the Z direction, reflectors are not required. This prevents propagation loss from occurring during propagation to the reflector. Therefore, even when the number of pairs of electrodes consisting of the electrodes 3 and 4 is reduced in an attempt to promote downsizing, the Q value is not easily reduced.

As illustrated in FIG. 4, the amplitude direction of the bulk wave in the first-order thickness-shear mode in a first region 451 included in the excitation region C of the piezoelectric layer 2 is the opposite in a second region 452 included in the excitation region C. FIG. 4 schematically illustrates a bulk wave when a voltage is applied between the electrode 3 and the electrode 4 so that the electrode 4 has a higher potential than the electrode 3. The first region 451 is a region between the first main surface 2a and a virtual plane VP1 that is orthogonal or substantially orthogonal to the thickness direction of the piezoelectric layer 2 and divides the piezoelectric layer 2 into two portions in the excitation region C. The second region 452 is a region between the virtual plane VP1 and the second main surface 2b in the excitation region C.

As described above, in the acoustic wave device 1, at least a pair of electrodes including the electrode 3 and the electrode 4 are arranged. However, since waves are not propagated in the X direction, the plurality of pairs of electrodes including the electrodes 3 and 4 are not always necessary. That is, only at least a pair of electrodes may be provided.

For example, the electrode 3 is an electrode connected to the hot potential, and the electrode 4 is an electrode connected to the ground potential. However, the electrode 3 may be connected to the ground potential and the electrode 4 may be connected to the hot potential. In this example embodiment, as described above, at least a pair of electrodes are the electrode connected to the hot potential or the electrode connected to the ground potential, and a floating electrode is not provided.

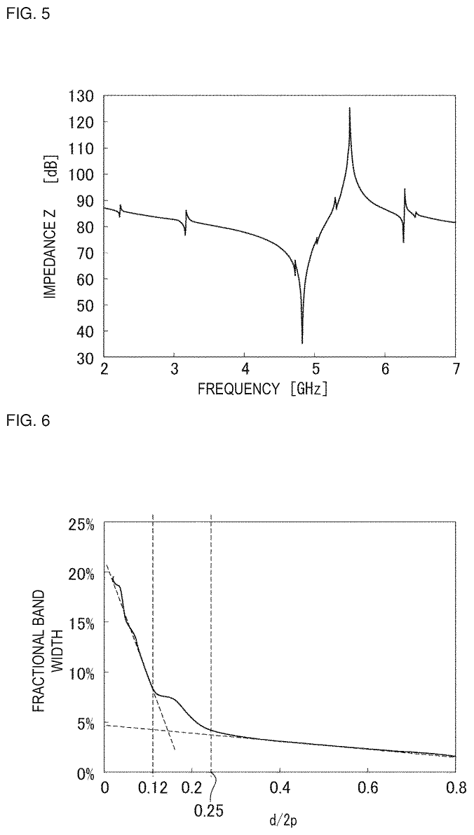

FIG. 5 is a diagram resonance illustrating characteristics of an acoustic wave device according to an example embodiment of the present invention. The design parameters of the acoustic wave device 1 having the resonance characteristics illustrated in FIG. 5 are as follows.
Piezoelectric layer 2: LiNbO₃ with Euler angles (0°, 0°, 90°)
Thickness of piezoelectric layer 2: about 400 nm
Length of region where electrodes 3 and 4 overlap as seen in direction orthogonal to longitudinal direction of electrodes 3 and 4, that is, excitation region C: about 40 μm
Number of pairs of electrodes consisting of electrodes 3 and 4: 21 pairs
Center-to-center distance between electrodes: about 3 μm
Width of electrodes 3 and 4: about 500 nm
d/p: about 0.133
Insulating layer 7: silicon oxide film with thickness of about 1 μm
Support 8: Si

The length of the excitation region C is a dimension of the excitation region C along the length direction of the electrodes 3 and 4.

In this example embodiment, the electrode-to-electrode distances of the electrode pairs including the electrodes 3 and 4 are all equal or substantially equal in the plurality of pairs. That is, the electrodes 3 and the electrodes 4 are arranged with equal or substantially equal pitches.

As is clear from FIG. 5, good resonance characteristics with the fractional band width of about 12.5% are obtained even though no reflector is provided.

As described above, in this example embodiment, d/p is, for example, less than or equal to about 0.5, more preferably less than or equal to about 0.24, where d is the thickness of the piezoelectric layer 2 and p is the center-to-center distance between the electrode 3 and the electrode 4. This will be described with reference to FIG. 6.

A plurality of acoustic wave devices are obtained in the same or similar manner as the acoustic wave device having the resonance characteristics illustrated in FIG. 5, except that d/2p is changed. FIG. 6 is a diagram illustrating a relationship between d/2p and a fractional band width of a resonator in the acoustic wave device.

As illustrated in FIG. 6, when d/2p exceeds about 0.25, that is, d/p>about 0.5, the fractional band width is less than about 5% even when d/p is adjusted. On the other hand, when d/2p ≤about 0.25, that is, d/p≤about 0.5, the fractional band width can be more than or equal to 5% by changing d/p within the range, that is, the resonator having a high coupling coefficient can be provided. In addition, when d/2p is less than or equal to about 0.12, that is, d/p is less than or equal to about 0.24, the fractional band width can be increased to more than or equal to about 7%. In addition, when d/p is adjusted within this range, a resonator having a wider fractional band width can be obtained, and a resonator having a higher coupling coefficient can be realized. Therefore, it is understood that by setting d/p to less than or equal to about 0.5 as in an acoustic wave device according to an example embodiment of the present invention, a resonator having a high coupling coefficient using the bulk wave in the first-order thickness-shear mode described above can be provided.

As described above, the at least one pair of electrodes may include a pair of electrodes, and in the case of one pair of electrodes, p is the center-to-center distance between the adjacent electrodes 3 and 4. Further, in the case of 1.5 or more pairs of electrodes, p may be the average distance of the center-to-center distances between the adjacent electrodes 3 and 4.

For the thickness d of the piezoelectric layer 2, when the piezoelectric layer 2 has variations in thickness d, a value obtained by averaging the thicknesses may be used.

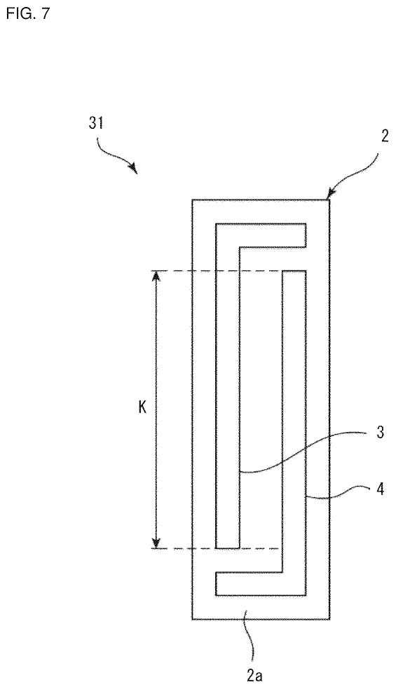

FIG. 7 is a plan view of another acoustic wave device according to an example embodiment of the present disclosure. In an acoustic wave device 31, a pair of electrodes including an electrode 3 and an electrode 4 are provided on a first main surface 2a of a piezoelectric layer 2. K in FIG. 7 is an intersecting width. As described above, in the acoustic wave device 31 of the present disclosure, the number of pairs of electrodes may be one. In this case, again, when d/p is less than or equal to 0.5, the bulk wave in the first-order thickness-shear mode can be effectively excited.

In the acoustic wave device 1, for example, it is preferable that the metallization ratio MR of any adjacent electrodes 3 and 4 of the plurality of electrodes 3 and 4 with respect to the excitation region, which is a region where the adjacent electrodes 3 and 4 overlap when viewed in their facing direction, satisfies MR≤ about 1.75 (d/p)+0.075. In other words, the excitation region (intersection region) is a region where a plurality of first electrode fingers and a plurality of second electrode fingers overlap when viewed in the direction in which adjacent first electrode fingers and second electrode fingers face each other, and, for example, it is preferable that the metallization ratio MR of the plurality of first electrode fingers and the plurality of second electrode fingers with respect to the excitation region satisfies MR≤ about 1.75 (d/p)+0.075. In that case, a spurious mode can be effectively reduced.

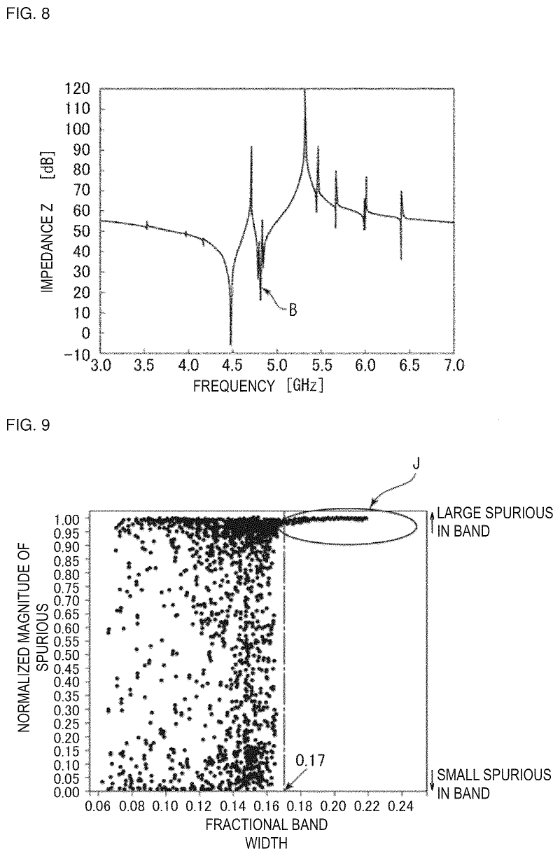

This will be described with reference to FIGS. 8 and 9. FIG. 8 is a reference diagram illustrating an example of the resonance characteristics of the acoustic wave device 1. A spurious mode indicated by an arrow B appears between a resonant frequency and an anti-resonant frequency. Note that d/p=about 0.08 and the Euler angles of LiNbO₃ are (0°, 0°, 90°). The metallization ratio MR is about 0.35, for example.

The metallization ratio MR will be described with reference to FIG. 1B. In the electrode structure of FIG. 1B, when focusing on a pair of electrodes 3 and 4, it is assumed that only this pair of electrodes 3 and 4 is provided. In this case, a portion surrounded by a dashed-dotted line C is the excitation region. When the electrode 3 and the electrode 4 are viewed in the direction orthogonal or substantially orthogonal to the length direction of the electrodes 3 and 4, that is, in their facing direction, the excitation region is a region of the electrode 3 that overlaps the electrode 4, a region of the electrode 4 that overlaps the electrode 3, and a region between the electrode 3 and the electrode 4 where the electrode 3 and the electrode 4 overlap each other. An area of the electrodes 3 and 4 in the excitation region C with respect to the area of the excitation region is the metallization ratio MR. That is, the metallization ratio MR is the ratio of the area of the metallization portion to the area of the excitation region.

When a plurality of pairs of electrodes are provided, the ratio of the metallization portion included in the entire excitation region to the total area of the excitation region may be MR.

FIG. 9 is a diagram illustrating a relationship between a fractional band width and a phase rotation amount of the spurious impedance normalized by about 180 degrees as the magnitude of the spurious when a large number of acoustic wave resonators are configured according to this example embodiment. The fractional band width is adjusted by changing the film thickness of the piezoelectric layer and the dimensions of the electrodes. FIG. 9 illustrates the results when a Z-cut LiNbO₃ piezoelectric layer is used, but the same tendency is obtained also when piezoelectric layers with other cut-angles are used.

In a region surrounded by an ellipse J in FIG. 9, the spurious is as large as about 1.0. As is clear from FIG. 9, when the fractional band width exceeds about 0.17, that is, exceeds about 17%, a large spurious with a spurious level of more than or equal to 1 appears in a pass band even when the parameters defining the fractional band width are changed. That is, as in the resonance characteristics illustrated in FIG. 8, a large spurious mode indicated by the arrow B appears within the band. Therefore, the fractional band width is, for example, preferably less than or equal to about 17%. In this case, the spurious mode can be reduced by adjusting the film thickness of the piezoelectric layer 2, the dimensions of the electrodes 3 and 4, or the like.

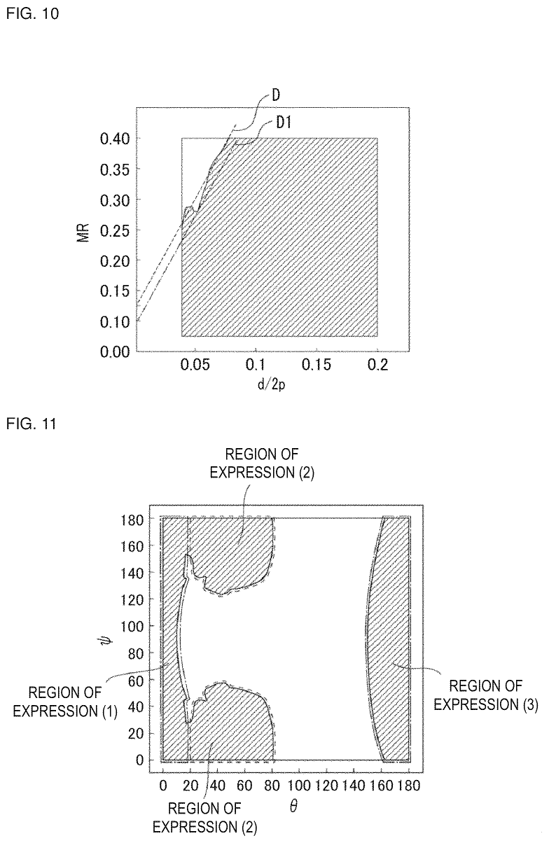

FIG. 10 is a diagram illustrating a relationship among d/2p, the metallization ratio MR, and the fractional band width. In the acoustic wave device, various acoustic wave devices 1 having different values of d/2p and different values of MR are provided, and the fractional band width is measured. A hatched portion to the right of a dashed line D illustrated in FIG. 10 is a region where the fractional band width is less than or equal to about 17%. The boundary between the hatched region and the non-hatched region is represented by MR=about 3.5 (d/2p)+0.075. That is, MR=about 1.75 (d/p)+0.075. Therefore, for example, MR≤about 1.75 (d/p)+0.075 is preferably satisfied. In this case, the fractional band width is easily set to less than or equal to about 17%. More preferably, for example, it is the region in FIG. 10 to the right of a dashed-dotted line DI indicating MR=about 3.5 (d/2p)+0.05. That is, when MR≤ about 1.75 (d/p)+0.05, the fractional band width can be reliably set to less than or equal to about 17%.

FIG. 11 is a diagram illustrating a map of the fractional band width with respect to the Euler angles (0°, θ, ψ) of LiNbO₃ when d/p is infinitely close to 0. A hatched portion in FIG. 11 is a region where the fractional band width of at least more than or equal to about 5% is obtained, and the range of the region is approximated by the following Expressions (1), (2), and (3).

(0°±10°, 0° to 20°, any ψ) Expression (1)

(0°±10°, 20° to 80°, 0° to 60° (1−(θ−50)²/900)^{1/2}) or (0°±10°, 20° to 80°, [180°−60° (1−(θ−50)²/900)^{1/2}] to) 180° Expression (2)

(0°±10°, [180°−30° (1−(ψ−90)²/8100)^{1/2}] to 180°, any ψ) Expression (3)

Therefore, in the case of the Euler angle range of Expression (1), Expression (2), or Expression (3), the fractional band width can be sufficiently widened, which is preferable.

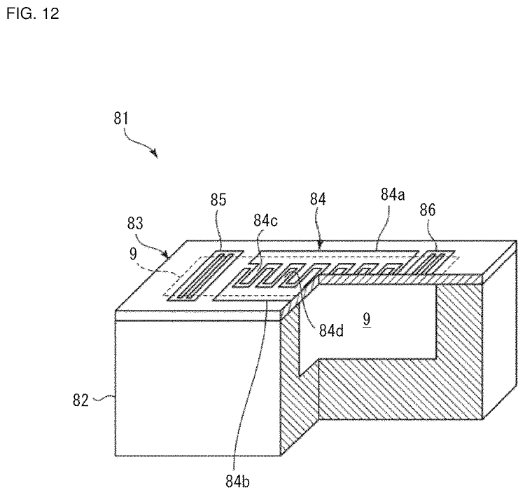

FIG. 12 is a partially cutaway perspective view for explaining an acoustic wave device according to a modification of an example embodiment of the present invention. An acoustic wave device 81 includes a support substrate 82. The support substrate 82 is provided with a recessed portion that is open on its upper surface. A piezoelectric layer 83 is laminated on the support substrate 82. A space portion 9 is thus formed. An IDT electrode 84 is provided on the piezoelectric layer 83 above the space portion 9. On both sides of the IDT electrode 84 in the acoustic wave propagation direction, reflectors 85 and 86 are provided. In FIG. 12, an outer periphery of the space portion 9 is indicated by a dashed line. Here, the IDT electrode 84 includes first and second busbars 84a and 84b, electrodes 84c defining and functioning as a plurality of first electrode fingers, and electrodes 84d serving as a plurality of second electrode fingers. The plurality of electrodes 84c are connected to the first busbar 84a. The plurality of electrodes 84d are connected to the second busbar 84b. The plurality of electrodes 84c and the plurality of electrodes 84d are interdigitated with each other.

In the acoustic wave device 81, a Lamb wave as a plate wave is excited by applying an AC electric field to the IDT electrode 84 above the space portion 9. Since the reflectors 85 and 86 are provided on both sides, resonance characteristics due to the Lamb wave can be obtained.

As described above, an acoustic wave device according to an example embodiment of the present invention may use plate waves.

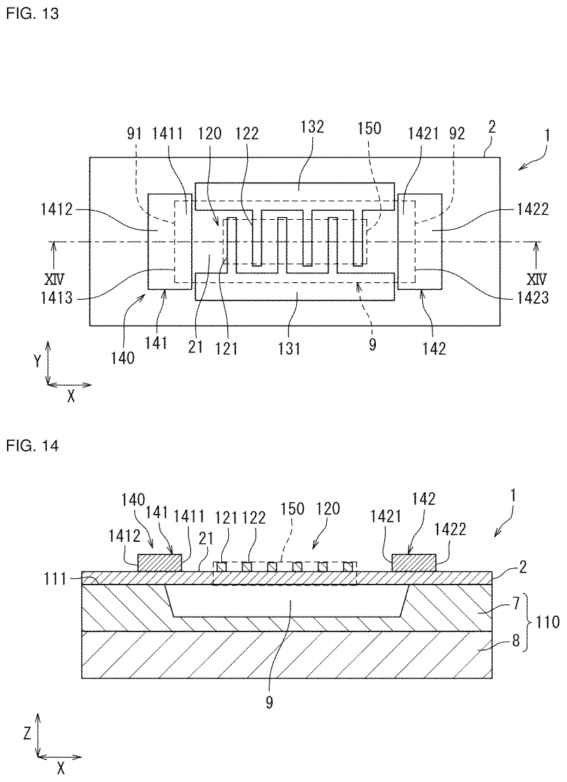

The acoustic wave device 1 according to the an example embodiment of the present invention will be described with reference to FIGS. 13 and 14. In this example embodiment, description of contents overlapping with the acoustic wave device according to the above-described example embodiment will be omitted as appropriate.

As illustrated in FIGS. 13 and 14, the acoustic wave device 1 includes a support substrate 110, a piezoelectric layer 2, a functional electrode 120, and at least one structure 140. In this example embodiment, the acoustic wave device 1 includes two structures (a first structure 141 and a second structure 142).

The support substrate 110 includes a space portion 9 therein. The space portion 9 is provided in one main surface 111 of the support substrate 110 that faces the piezoelectric layer 2. In this example embodiment, the support substrate 110 includes a support 8 and an insulating layer (an example of a bonding layer) 7 provided on the support 8, and the space portion 9 is provided in the insulating layer 7. The space portion 9 has a rectangular or substantially rectangular shape in plan view along the lamination direction Z.

The piezoelectric layer 2 is provided on one main surface 111 of the support substrate 110. In this example embodiment, the piezoelectric layer 2 is provided on the insulating layer 7 in the lamination direction (for example, Z direction) of the support substrate 110 and the piezoelectric layer 2. The piezoelectric layer 2 includes a membrane portion 21. The membrane portion 21 defines a portion of the piezoelectric layer 2 that at least partially overlaps with the space portion 9 in the lamination direction Z, for example. In the membrane portion 21, the functional electrode 120 is positioned and a functional electrode region (intersection region) 150 is provided.

The functional electrode 120 is provided on the piezoelectric layer 2 in the lamination direction Z. The functional electrode 120 is configured so as to at least partially overlap with the space portion 9 in plan view along the lamination direction Z.

In this example embodiment, the functional electrode 120 is, for example, an IDT electrode including a plurality of electrode fingers, and is located between two wiring electrodes 131 and 132 arranged on the piezoelectric layer 2 with a gap in a first direction (for example, Y direction) intersecting the lamination direction Z. The plurality of electrode fingers of the functional electrode 120 each extend along the first direction (electrode finger extending direction) Y, and are located with a gap in a second direction X intersecting the lamination direction Z and the first direction Y. That is, the functional electrode 120 includes a first electrode finger 121 and a second electrode finger 122 that face each other in the second direction (electrode finger facing direction) X. The first electrode finger 121 and the second electrode finger 122 are adjacent electrodes, and a region where the first electrode finger 121 and the second electrode finger 122 overlap when viewed along the second direction constitutes the functional electrode region 150. As an example, the first electrode finger 121 is connected to the wiring electrode 131, and the second electrode finger 122 is connected to the wiring electrode 132.

The first structure 141 and the second structure 142 are each provided on the piezoelectric layer 2 and configured to have a smaller coefficient of thermal linear expansion than the piezoelectric layer 2. The first structure 141 and the second structure 142 are each configured to be able to pull the membrane portion 21 toward the outer side of the membrane portion 21 (in other words, in a direction in which the membrane portion 21 expands) in plan view along the lamination direction Z. For example, the first structure 141 and the second structure 142 each include a material having a smaller coefficient of thermal linear expansion than the material of the piezoelectric layer 2, or a heat-shrinkable resin material such as, for example, epoxy resin, or a material that shrinks by reaction with water. The first structure 141 and the second structure 142 include a region located in a region of the piezoelectric layer 2 that is other than the region where the functional electrode 120 is provided and that does not overlap with the space portion 9 in plan view along the lamination direction Z.

In this example embodiment, the first structure 141 and the second structure 142 have a rectangular or substantially rectangular parallelepiped shape, as an example, and are arranged such that the functional electrode 120 is located between the first structure 141 and the second structure 142 in the second direction X.

The first structure 141 is located at one end 91 of the space portion 9 in the second direction X and includes the following regions. The following regions do not overlap with the functional electrode region 150 in plan view along the lamination direction Z.
A region 1411 located in a region overlapping with the space portion 9 of the piezoelectric layer 2 in plan view along the lamination direction Z
A region 1412 located in a region not overlapping with the space portion 9 of the piezoelectric layer 2 in plan view along the lamination direction Z
A region 1413 located on the boundary between the region overlapping with the space portion 9 of the piezoelectric layer 2 and the region not overlapping with the space portion 9 in plan view along the lamination direction Z

The second structure 142 is located at the other end 92 of the space portion 9 in the second direction X and includes the following regions. The following regions do not overlap with the functional electrode region 150 in plan view along the lamination direction Z.
A region 1421 located in a region overlapping with the space portion 9 of the piezoelectric layer 2 in plan view along the lamination direction Z
A region 1422 located in a region not overlapping with the space portion 9 of the piezoelectric layer 2 in plan view along the lamination direction Z
A region 1423 located on the boundary between the region overlapping with the space portion 9 of the piezoelectric layer 2 and the region not overlapping with the space portion 9 in plan view along the lamination direction Z

In other words, the structure 140 includes the following regions, and is located in a region not overlapping with the functional electrode region 150 in plan view along the lamination direction Z.

The regions 1412 and 1422 located in a region of the piezoelectric layer 2 that is on at least one side (both sides in this example embodiment) of the IDT electrode 120 in the electrode finger facing direction X and that does not overlap with the space portion 9 in plan view along the lamination direction Z.

The regions 1413 and 1423 located in a region of the piezoelectric layer 2 that is on at least one side (both sides in this example embodiment) of the IDT electrode 120 in the electrode finger facing direction X and that is on the boundary between the region overlapping with the space portion 9 and the region not overlapping with the space portion 9 in plan view along the lamination direction Z.

The first structure 141 and the second structure 142 are each configured such that the regions 1412 and 1422 located in the region not overlapping with the space portion 9 of the piezoelectric layer 2 are larger than the regions 1411 and 1421 located in the region overlapping with the space portion 9 of the piezoelectric layer 2.

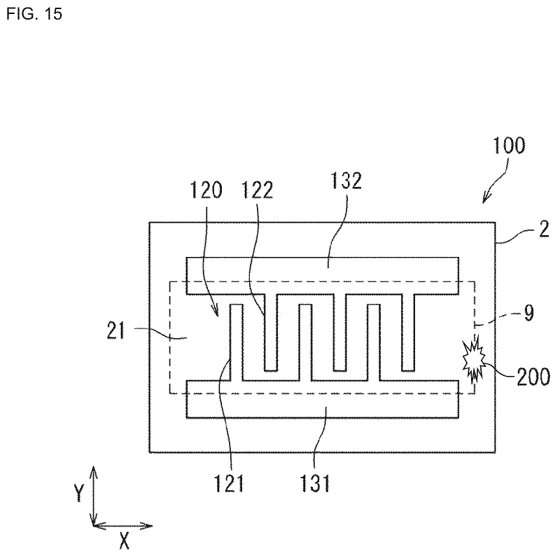

It is assumed, for example, that a crack 200 occurs in a region without the functional electrode 120 in an acoustic wave device 100 not including the structure 140 as illustrated in FIG. 15. In this case, since the crack 200 does not affect main characteristics of a filter, the crack 200 may be undetectable from the main characteristics. The presence of the crack 200 makes the acoustic wave device 100 more susceptible to breakage due to mechanical impact and the like. It has also been discovered that a gap formed by the crack 200 in the acoustic wave device 100 prevents propagation of acoustic vibration, thus causing a peak waveform to appear in a frequency band that is not the main characteristic. However, the early-stage crack 200 may be difficult to detect because the gap is small.

The acoustic wave device 1 includes a support substrate 110 including a space portion 9 therein, a piezoelectric layer 2 provided on the support substrate 110, a functional electrode 120 provided on the piezoelectric layer 2 and at least partially overlapping with the space portion 9 in plan view along the lamination direction Z, and at least one structure 140 provided on the piezoelectric layer 2 and having a smaller coefficient of thermal linear expansion than the piezoelectric layer 2. The structure 140 includes regions 1412 and 1422 located in a region of the piezoelectric layer 2 that is other than a region where the functional electrode 120 is provided and that does not overlap with the space portion 9 in plan view along the lamination direction Z. With this configuration, if a crack occurs in a region of the membrane portion 21 where the functional electrode 120 is not provided, for example, the membrane portion 21 is pulled toward the outer side of the membrane portion 21 by the structure 140, increasing the gap formed by the crack, and the acoustic effect can be made apparent. As a result, the acoustic wave device 1 can be obtained that can easily detect a crack occurring in the membrane portion 21 from the filter characteristics.

The acoustic wave device 1 can optionally include any one or more of the following configurations. In other words, any one or more of the following configurations can be optionally deleted if they are included in the above example embodiments, and can be optionally added if they are not included in the above example embodiments. By providing such a configuration, the acoustic wave device 1 can be more reliably obtained that can easily detect a crack occurring in the membrane portion 21.

The functional electrode 120 is, for example, an IDT electrode.

The structure 140 includes regions 1412 and 1422 located in a region of the piezoelectric layer 2 that is on at least one side of the IDT electrode 120 in the electrode finger facing direction X and that does not overlap with the space portion 9 in plan view along the lamination direction z.

The structure 140 includes regions 1413 and 1423 located in a region of the piezoelectric layer 2 that is on at least one side of the IDT electrode 120 in the electrode finger facing direction X and that is at the boundary between the region overlapping with the space portion 9 and the region not overlapping with the space portion 9 in plan view along the lamination direction Z.

The functional electrode 120 is an IDT electrode and includes a first electrode finger 121 and a second electrode finger 122 that face each other in the second direction X. When a region where the first electrode finger 121 and the second electrode finger 122 overlap as viewed along the second direction X is defined as a functional electrode region 150, the structure 140 is located in a region other than the functional electrode region 150.

The acoustic wave device 1 of this example embodiment can also be configured as follows.

The acoustic wave device 1 is not limited to including the first structure 141 and the second structure 142 as the structure 140. For example, the acoustic wave device 1 may include only one of the first structure 141 and the second structure 142, or may include one or more other structures 140 in addition to the first structure 141 and the second structure 142.

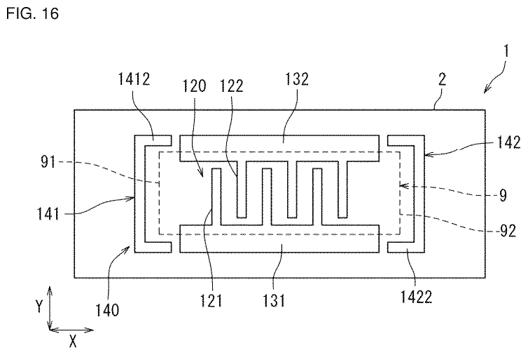

The first structure 141 and the second structure 142 are each not limited to including three regions. For example, as illustrated in FIG. 16, the first structure 141 and the second structure 142 may each include only regions 1412 and 1422 located in regions that do not overlap with the space portion 9 of the piezoelectric layer 2 in plan view along the lamination direction Z. In this case, the acoustic wave device 1 includes a plurality of structures 140 and is configured so that at least one of the plurality of structures 140 is located in the following region.
A region of the piezoelectric layer 2 on one side of the IDT electrode 120 in the electrode finger facing direction X, which does not overlap with the space portion 9 in plan view along the lamination direction Z
A region on the other side of the IDT electrode 120 in the electrode finger facing direction X, which does not overlap with the space portion 9 in plan view along the lamination direction Z

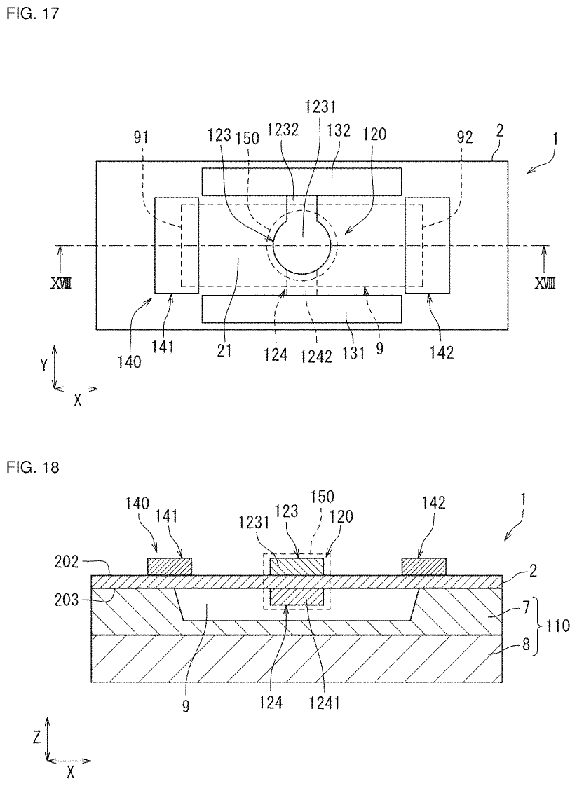

The functional electrode 120 is not limited to the IDT electrode including a plurality of electrode fingers. For example, as illustrated in FIGS. 17 and 18, the functional electrode 120 may include an upper electrode 123 provided on one main surface 202 of the piezoelectric layer 2 and a lower electrode 124 provided on the other main surface 203 of the piezoelectric layer 2. The acoustic wave device 1 in FIGS. 17 and 18 is, for example, a BAW device including a single crystal piezoelectric film (lithium niobate or lithium tantalate, for example) and can be formed using a sacrificial layer method (a method of forming a space portion 9 using a sacrificial layer). The upper electrode 123 includes, for example, a first portion 1231 having a circular or substantially circular shape in plan view along the lamination direction Z and a second portion 1232 connecting the first portion 1231 to a wiring portion 132. The lower electrode 124 includes, for example, a first portion 1241 having a circular or substantially circular shape in plan view along the lamination direction Z and a second portion 1242 connecting the first portion 1241 to a wiring portion 131. The lower electrode 124 is located in the space portion 9. The first portion 1231 of the upper electrode 123 and the first portion 1241 of the lower electrode 124 overlap in plan view along the lamination direction Z to define a functional electrode region 150. The two structures 141 and 142 are located in a region other than the functional electrode region 150.

The regions 1411 and 1421 located in the region overlapping with the space portion 9 of the piezoelectric layer 2 in each of the first structure 141 and the second structure 142 may overlap with or does not have to overlap with the functional electrode region 150 in plan view along the lamination direction Z.

The acoustic wave device 1 can be manufactured using any method, for example, such as a method of forming a space portion 9 using a sacrificial layer or a method of etching the support substrate 110 from the back side.

The support substrate 110 is not limited to including a support 8 and an insulating layer 7 provided on the support 8, and may be configured to include the support 8 only.

At least a portion of the configuration of the acoustic wave device 1 may be added to acoustic wave devices according to example embodiments of the present invention, or at least a portion of the configuration of acoustic wave devices according to example embodiments of the present invention may be added to the acoustic wave device 1.

Various example embodiments of the present invention have been described above in detail with reference to the drawings.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a support substrate including a space portion on one main surface thereof;
a piezoelectric body layer on the one main surface of the support substrate;
a functional electrode on the piezoelectric body layer and at least partially overlapping with the space portion in plan view along a lamination direction of the support substrate and the piezoelectric body layer; and
at least one structure on the piezoelectric body layer and having a smaller coefficient of thermal linear expansion than the piezoelectric body layer; wherein
the at least one structure includes a region located in a region of the piezoelectric body layer other than a region where the functional electrode is provided and that does not overlap with the space portion in the plan view.

2. The acoustic wave device according to claim 1, wherein the functional electrode is an IDT electrode.

3. The acoustic wave device according to claim 2, wherein the at least one structure includes a region located in a region of the piezoelectric body layer that is on at least one side of the IDT electrode in an electrode finger facing direction and that does not overlap with the space portion in the plan view.

4. The acoustic wave device according to claim 2, wherein the at least one structure includes a region located in a region of the piezoelectric body layer that is on at least one side of the IDT electrode in an electrode finger facing direction and that is at a boundary between a region overlapping with the space portion and a region not overlapping with the space portion in the plan view.

5. The acoustic wave device according to claim 2, further comprising:
a plurality of the structures; wherein
the plurality of structures are located respectively in a region of the piezoelectric body layer on one side of the IDT electrode in an electrode finger facing direction, which does not overlap with the space portion in the plan view, and a region of the piezoelectric body layer on another side of the IDT electrode in the electrode finger facing direction, which does not overlap with the space portion in the plan view.

6. The acoustic wave device according to claim 2, wherein
the IDT electrode includes a first electrode finger and a second electrode finger facing each other in an electrode finger facing direction; and
when a region where the first electrode finger and the second electrode finger overlap as viewed along the electrode finger facing direction is defined as a functional electrode region, the at least one structure is located in a region that does not overlap with the functional electrode region in the plan view.

7. The acoustic wave device according to claim 2, wherein the piezoelectric body layer includes lithium niobate or lithium tantalate;
the IDT electrode includes a first electrode finger and a second electrode finger facing each other in a direction intersecting the lamination direction;
the first electrode finger and the second electrode finger are adjacent electrodes; and
d/p is less than or equal to about 0.5, where d is a thickness of the piezoelectric body layer and p is a center-to-center distance between the first electrode finger and the second electrode finger.

8. The acoustic wave device according to claim 7, wherein d/p is less than or equal to about 0.24.

9. The acoustic wave device according to claim 7, wherein MR≤about 1.75 (d/p)+0.075 is satisfied, where MR is a metallization ratio that is a ratio of an area of the first electrode finger and the second electrode finger in an excitation region to the excitation region, the excitation region being a region where the first electrode finger and the second electrode finger overlap each other in a direction intersecting the lamination direction.

10. The acoustic wave device according to claim 2, wherein
the piezoelectric body layer includes lithium niobate or lithium tantalate; and
Euler angles (φ, θ, ψ) of the lithium niobate or lithium tantalate are within a range of Expression (1), Expression (2), or Expression (3):
(0°±10°, 0° to 20°, any ψ) Expression (1);
(0°±10°, 20° to 80°, 0° to 60° (1−(θ−50)²/900)^{1/2}) or (0°±10°, 20° to 80°, [180°−60°(1−(θ−50)²/900)^{1/2}] to) 180° Expression (2); and
(0°±10°, [180°−30°(1−ψ−90)²/8100)^{1/2}] to 180°, any ψ) Expression (3).

11. The acoustic wave device according to claim 1, wherein
the piezoelectric body layer includes lithium niobate or lithium tantalate; and
the acoustic wave device is structured to generate a bulk wave in a thickness-shear mode.

12. The acoustic wave device according to claim 1, wherein
the piezoelectric body layer includes lithium niobate or lithium tantalate; and
the acoustic wave device is structured to generate a plate wave.

13. The acoustic wave device according to claim 1, wherein the functional electrode includes an upper electrode on one main surface of the piezoelectric body layer and a lower electrode on another main surface of the piezoelectric body layer.

14. The acoustic wave device according to claim 13, wherein the piezoelectric body layer includes single crystal lithium niobate or lithium tantalate.

15. The acoustic wave device according to claim 1, wherein the at least one structure includes a heat-shrinkable resin material.

16. The acoustic wave device according to claim 1, wherein the at least one structure includes a material that shrinks by reaction with water.

17. The acoustic wave device according to claim 6, wherein a width of each of the first and second electrodes is more than or equal to about 150 nm and less than or equal to about 1000 nm.

18. The acoustic wave device according to claim 1, wherein
the support substrate includes a support and an insulating layer on the support; and
the space portion is provided in the insulating layer.

19. The acoustic wave device according to claim 18, wherein the support includes Si.

20. The acoustic wave device according to claim 18, wherein the insulating layer includes silicon oxide.
